(19) United States
(12) Patent Application Publication
(10) Pub. No.: US 2014/0209785 A1
(43) Pub. Date: Jul. 31, 2014

(54) Image Capture Device with Shared Image Sensing Element

(71) Applicants: Asia Optical International Ltd., Tortola (GB); Sintai Optical (Shenzhen) Co., Ltd., Shenzhen City (CN)

(72) Inventor: Chun-Yu Hsueh, Taichung (TW)

(73) Assignees: Asia Optical International Ltd., Tortola (GB); Sintai Optical (Shenzhen) Co., Ltd., Shenzhen City (CN)

(21) Appl. No.: 14/166,885

(22) Filed: Jan. 29, 2014

(30) Foreign Application Priority Data
Jan. 29, 2013 (TW) 102201864

(51) Int. Cl. H01L 27/146

(52) U.S. Cl. CPC H01L 27/14625
USPC 250/208.1

(57) ABSTRACT

An image capture device includes a plurality of focus driving elements, a plurality of lenses, and an image sensing element. The lenses are respectively driven by the focusing driving elements to perform focus operation. The image sensing element selectively receives an image through one of the lenses.

### BACKGROUND OF THE INVENTION

1. Field of the Invention

The invention relates to an image capture device with a shared image sensing element.

2. Description of the Related Art

A conventional image capture device has a zoom lens to perform a zooming operation. However, a zoom lens generally has a long dimension which is unfavorable to thinning of an image capture device.

### BRIEF SUMMARY OF THE INVENTION

To address the shortcomings discussed, the invention provides an image capture device, wherein a zoom lens having a long dimension is replaced with a plurality of lenses having different focal lengths. The lenses jointly use an image sensing element rather than respectively use one. Also, each lens is driven by an independent focus driving element. By the arrangements, the image capture device is thinner and the control of focus operation is simple.

The image capture device in accordance with an exemplary embodiment of the invention includes a plurality of focus driving elements, a plurality of lenses, and an image sensing element. The lenses are respectively driven by the focusing driving elements to perform focus operation. The image sensing element selectively receives an image through one of the lenses.

In another exemplary embodiment, the image capture device further includes a zoom driving element configured to drive the lenses and the focus driving elements so that the image sensing element receives the image through the one of the lenses.

In yet another exemplary embodiment, the image capture device further includes a zoom driving element configured to drive the image sensing element so that the image sensing element receives the image through the one of the lenses.

In another exemplary embodiment, the lenses have focal lengths different from each other.

In yet another exemplary embodiment, the lenses are arranged in a line.

In another exemplary embodiment, the lenses are arranged in a circle.

In yet another exemplary embodiment, the image sensing element is a charge coupled device.

In another exemplary embodiment, the image sensing element is a complementary metal oxide semiconductor device.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 depicts an image capture device with a shared image sensing element in accordance with a first embodiment of the invention; and

FIG. 2 depicts an image capture device with a shared image sensing element in accordance with a second embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

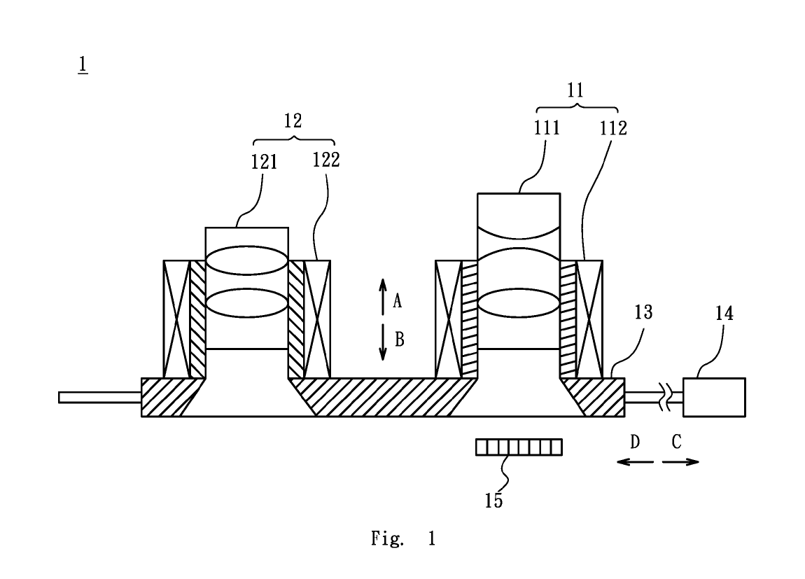

FIG. 1 is an image capture device with a shared image sensing element in accordance with a first embodiment of the invention, wherein the image capture device 1 includes a plurality of lens modules 11, 12 which have different effective focal lengths and jointly use an image sensing element 15. In zooming operation, the lens module 11 and the lens module 12 can be switched so that one of them is directed at the image sensing element 15. In FIG. 1, for example, the lens module 11 is directed at the image sensing element 15.

In the first embodiment, the lens modules 11, 12 are disposed in a line on a lens module fixing plate 13. A zoom driving element 14 is connected to the lens module fixing plate 13 for driving the lens modules 11, 12 in direction C or D in zooming operation.

The lens module 11 includes a lens 111 and a focus driving element 112. Referring to FIG. 1, the lens module 11 is directed at the image sensing element 15 when selected to capture an image. The lens 111 is driven by the focus driving elements 112 in direction A or B in focus operation. Thus, an optical image can be received by the image sensing element 15 through the lens module 11 and converted into an electronic image for the subsequent processing and storage.

The lens module 12 includes a lens 121 and a focus driving element 122. To use the lens module 12, the zoom operation is performed wherein the lens module fixing plate 13 is driven by the zoom driving element 14 in direction C so that the lens module 12 is directed at the image sensing element 15, and the focus operation is performed wherein the lens 121 is driven by the focus driving element 122 in direction A or B so that an image can be captured by the lens module 12.

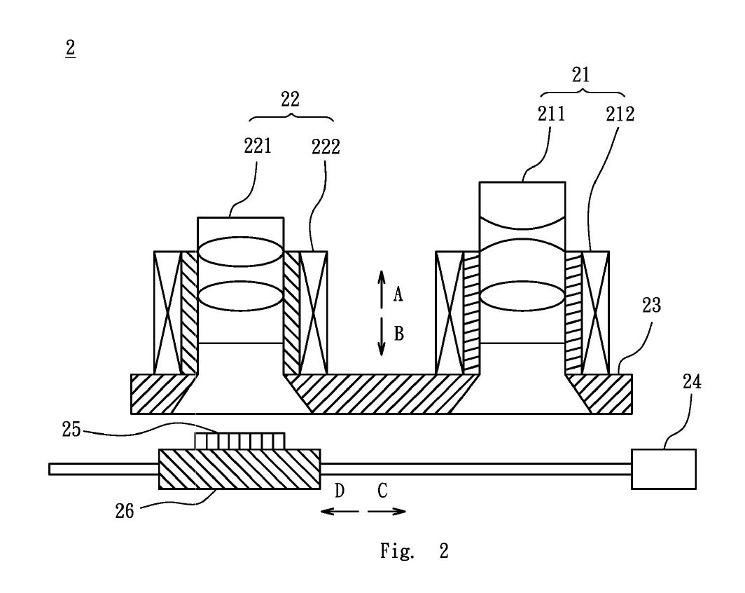

FIG. 2 is an image capture device with a shared image sensing element in accordance with a second embodiment of the invention, wherein the image capture device 2 includes a plurality of lens modules 21, 22 which have different effective focal lengths and jointly use an image sensing element 25. In zooming operation, the image sensing element 25 is moved and directed at the lens module 21 or 22. In FIG. 2, for example, the image sensing element 25 is directed at the lens module 22.

In the second embodiment, the lens modules 21, 22 are disposed in a line on a lens module fixing plate 23. The image sensing element 25 is disposed on an image sensing element fixing plate 26. A zoom driving element 24 is connected to the image sensing element fixing plate 26 for driving the image sensing element 25 in direction C or D in zooming operation.

The lens module 22 includes a lens 221 and a focus driving element 222. Referring to FIG. 2, the image sensing element 25 is directed at the lens module 22 when the lens module 22 is selected to capture an image. The lens 221 is driven by the focus driving elements 222 in direction A or B in focus operation. Thus, an optical image can be received by the image sensing element 25 through the lens module 22 and converted into an electronic image for the subsequent processing and storage.

The lens module 21 includes a lens 211 and a focus driving element 212. To use the lens module 21, the zoom operation is performed wherein the image sensing element fixing plate 26 is driven by the zoom driving element 24 in direction C so that the image sensing element 25 is directed at the lens module 21, and the focus operation is performed wherein the lens 211 is driven by the focus driving element 212 in direction A or B so that an image can be captured by the lens module 21.

In the first embodiment, the image sensing element 15 is stationary and the lens modules 11, 12 are moved to perform the zoom operation. In the second embodiment, however, the lens modules 21, 22 are stationary and the image sensing element 25 is moved to perform the zoom operation.

In the above embodiments, the lens modules are disposed in a line on the lens module fixing plate. It is understood that the lens modules can be disposed in a circle on the lens module fixing plate, which also belongs to the category of the invention.

In the above embodiments, the image sensing element may be a charge coupled device (CCD) or a complementary metal oxide semiconductor (CMOS) device, to receive the optical images through the lens modules and convert the optical images into the electronic images for output, image processing, and storage.

In conclusion, the invention provides an image capture device with a shared image sensing element, wherein the lens modules jointly use an image sensing element rather than respectively use one. Also, each lens module is provided with an independent focus driving element. By the arrangements, the image capture device is thinner and the control of focus operation is simple.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An image capture device, comprising:
a plurality of focus driving elements;
a plurality of lenses, respectively driven by the focusing driving elements to perform focus operation; and
an image sensing element selectively receiving an image through one of the lenses.

2. The image capture device as claimed in claim 1, further comprising a zoom driving element configured to drive the lenses and the focus driving elements so that the image sensing element receives the image through the one of the lenses.

3. The image capture device as claimed in claim 1, further comprising a zoom driving element configured to drive the image sensing element so that the image sensing element receives the image through the one of the lenses.

4. The image capture device as claimed in claim 1, wherein the lenses have focal lengths different from each other.

5. The image capture device as claimed in claim 1, wherein the lenses are arranged in a line.

6. The image capture device as claimed in claim 1, wherein the lenses are arranged in a circle.

7. The image capture device as claimed in claim 1, wherein the image sensing element is a charge coupled device.

8. The image capture device as claimed in claim 1, wherein the image sensing element is a complementary metal oxide semiconductor device.
